(19) United States
(12) Patent Application Publication
(10) Pub. No.: US 2010/0164756 A1
(43) Pub. Date: Jul. 1, 2010

(54) Electronic device user input

(75) Inventor: Aki Henrik Vanninen, (US)

Correspondence Address: HARRINGTON & SMITH, 4 RESEARCH DRIVE, Suite 202, SHELTON, CT, 06484-6212, US

(73) Assignee: Nokia Corporation

(21) Appl. No.: 12/319,008

(22) Filed: Dec. 30, 2008

(51) Int. Cl. H03M 11/00

(52) U.S. Cl. 341/22

(57) ABSTRACT

Disclosed herein is an apparatus. The apparatus includes a user input region and a sensor system. The user input region includes a plurality of keys. The sensor system is proximate the user input region. The sensor system is configured to determine a touch on a first one of the plurality of keys of the user input region. The sensor system is configured to determine a direction of the touch on the first one of the plurality of keys. The sensor system is configured to indicate a selection of a second one of the plurality of keys based on the determined direction of the touch on the first one of the plurality of keys.

### BACKGROUND

1. Field of the Invention

The invention relates to an electronic device and, more particularly, to electronic device user input.

2. Brief Description of Prior Developments

As electronic devices become smaller and smaller, this generally results in a decreased size of the user input region (or keyboard) of the device. This adds further limitations in devices having a full QWERTY keyboard. For example, when a user of such a device is using the keyboard, the user's finger can hide several of the keys of keyboard making it difficult to know what key is being pressed. Additionally, as consumers demand increased functionality from electronic devices, there is a need to provide devices having increased capabilities while maintaining robust and reliable product configurations. Further, due to the demand for miniaturized devices, the increased capabilities should be provided in a compact yet user-friendly design.

The demand for continuous size miniaturization generates challenges to implement added user input functionality. Accordingly, there is a need to provide improved user input functionality for an electronic device.

### SUMMARY

In accordance with one aspect of the invention, an apparatus is disclosed. The apparatus includes a user input region and a sensor system. The user input region includes a plurality of keys. The sensor system is proximate the user input region. The sensor system is configured to determine a touch on a first one of the plurality of keys of the user input region. The sensor system is configured to determine a direction of the touch on the first one of the plurality of keys. The sensor system is configured to indicate a selection of a second one of the plurality of keys based on the determined direction of the touch on the first one of the plurality of keys.

In accordance with another aspect of the invention, a method is disclosed. A plurality of keys forming a user input region is provided. A sensor system is provided proximate the plurality of keys. The sensor system is configured to indicate a selection of a first one of the plurality of keys in response to a movement on the user input region at a distance from the first one of the plurality of keys.

In accordance with another aspect of the invention, a method is disclosed. A touch on a first one of a plurality of keys of a user input region is sensed. A direction of the touch on the first one of the plurality of keys is determined. A selection of a second one of the plurality of keys is indicated based on the determined direction of the touch on the first one of the plurality of keys.

In accordance with another aspect of the invention, a program storage device readable by a machine, tangibly embodying a program of instructions executable by the machine for performing operations to select a key of a user input region is disclosed. A touch on a first one of a plurality of keys of a user input region is sensed. The first one and a second one of the plurality of keys are displayed on a display. The second one of the plurality of keys is highlighted on the display in response to a movement on the first one of the plurality of keys.

### BRIEF DESCRIPTION OF THE DRAWINGS

The foregoing aspects and other features of the invention are explained in the following description, taken in connection with the accompanying drawings, wherein:

FIG. 1 is a front view of an electronic device incorporating features of the invention;

FIG. 2 is another front view of the device shown in FIG. 1 with virtual keys shown in the display;

FIG. 3 is another front view of the device shown in FIG. 1 with virtual keys shown in the display;

FIG. 4 is another front view of the device shown in FIG. 1 with virtual keys shown in the display;

FIG. 5 is an enlarged view of a portion of the keyboard of the device shown in FIG. 1;

FIG. 6 is front view of a portion of a keyboard in accordance with another embodiment of the invention;

FIG. 7 is a front view of another electronic device incorporating features of the invention;

FIG. 8 is a front view of another electronic device incorporating features of the invention;

FIG. 9 is a block diagram of an exemplary method of the device shown in FIGS. 1, 7, and 8;

FIG. 10 is a block diagram of another exemplary method of the device shown in FIGS. 1, 7, and 8; and

FIG. 11 is a schematic drawing illustrating components of the device shown in FIGS. 1, 7, and 8.

### DETAILED DESCRIPTION

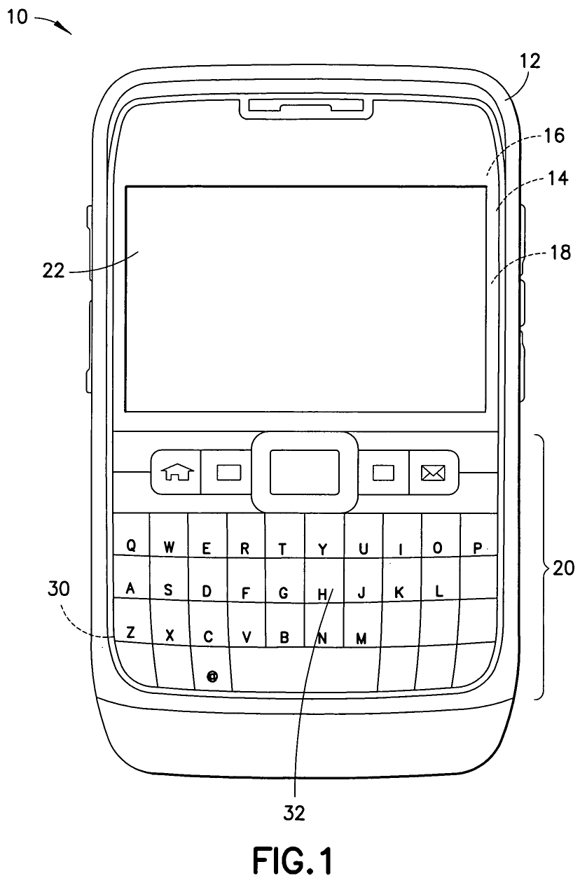

Referring to FIG. 1, there is shown a front view of an electronic device 10 incorporating features of the invention. Although the invention will be described with reference to the exemplary embodiments shown in the drawings, it should be understood that the invention can be embodied in many alternate forms of embodiments. In addition, any suitable size, shape or type of elements or materials could be used.

According to one example of the invention, the device 10 is a multi-function portable electronic device. However, in alternate embodiments, features of the various embodiments of the invention could be used in any suitable type of portable electronic device such as a mobile phone, a gaming device, a music player, a notebook computer, or a PDA, for example. In addition, as is known in the art, the device 10 can include multiple features or applications such as a camera, a music player, a game player, or an Internet browser, for example. The device 10 generally comprises a housing 12, a transceiver 14 connected to an antenna 16, electronic circuitry 18, such as a controller and a memory for example, within the housing 12, a user input region 20 and a display 22. The display 22 could also form a user input section, such as a touch screen. It should be noted that in alternate embodiments, the device 10 can have any suitable type of features as known in the art.

According to various exemplary embodiments of the invention, the user input region 20 may comprise a keyboard or keypad having a plurality of keys, for example. Additionally, the keyboard may be QWERTY keyboard for example. Further, according to some embodiments, the keyboard may comprise the number keys “1-9” and “0” above the QWERTY layout. However, any suitable user input or keyboard layout may be provided.

The device 10 further comprises a sensor system 30 proximate the user input region (or keyboard) 20. The sensor system 30 may comprise capacitive touch sensors and/or proximity sensors configured to detect a contact (or a touch) and/or movement on the keyboard 20 by a user's finger (and/or stylus or pen). The capacitive touch sensors and the proximity sensors may also sense the contact or movement on each of the individual keys. It should be noted that the capacitive touch sensors and proximity sensors are not required. For example, a sensor system comprising resistive, acoustic, and/or optical configurations may be provided. However, any suitable type of sensor system having touch and proximity sensing capability may be provided. Additionally, it should be noted that the sensor system may be separate from the keyboard. Alternatively, according some embodiments, the sensor system (including the capacitive touch sensors and the proximity sensors) may be integrated in the keyboard. However, any suitable keyboard and sensor system configuration wherein finger presence, movement, and finger press/touch on the keyboard may be sensed or detected may be provided.

Various embodiments of the invention provide for an improved keyboard typing experience for portable electronic devices. For example, a view of a key and the surrounding keys as the user's finger is detected to be touching the key is displayed (on the display 22). This allows for the user to see if the correct key is being pressed.

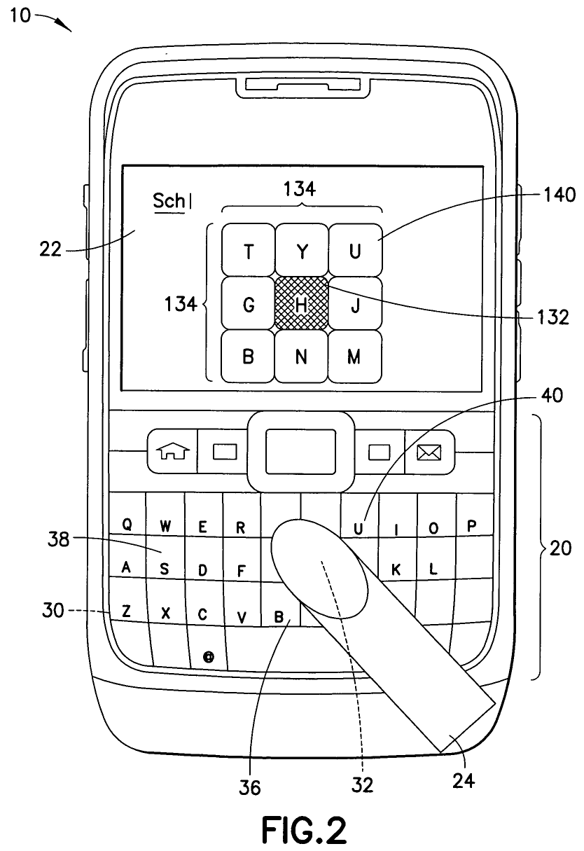

For example, referring now also to FIG. 2, when the presence of the user's finger 24 is detected on the keyboard 20, the area of the closest surrounding keys is displayed on the display 22 as virtual keys. For example, a group of eight surrounding keys may be displayed. However, any suitable number of surrounding keys may be shown in the display 22. In addition, the key where the touch is sensed is highlighted on the display 22. The highlighted key may be referred to as the active key. As shown in FIG. 2, in this example, the presence of the user's finger 24 is detected (by the sensor system 30) to be proximate the “H” key 32 on the keyboard 20. As the “H” key 32 is the detected key, a corresponding virtual “H” key 132 (along with corresponding surrounding virtual keys 134) is displayed on the display 22, and the “H” key is now the ‘active’ key. If the highlighted active key is correct one (or the key intended to be pressed), then the user may press (or touch) the keyboard a ‘second time’ to select (or confirm the selection) of the key. The press or touch (‘second time’) on the keyboard 20 to confirm the selection of the key may be a press or touch on the selected key itself (in this example, the “H” key 32). However, according to some embodiments of the invention, the ‘second time’ press or touch to confirm the selection of the highlighted key may be performed on any of the keys on the keyboard 20. Such as a press on the “B” key 36, or a press on the “S” key 38, or any other key on the keyboard 20.

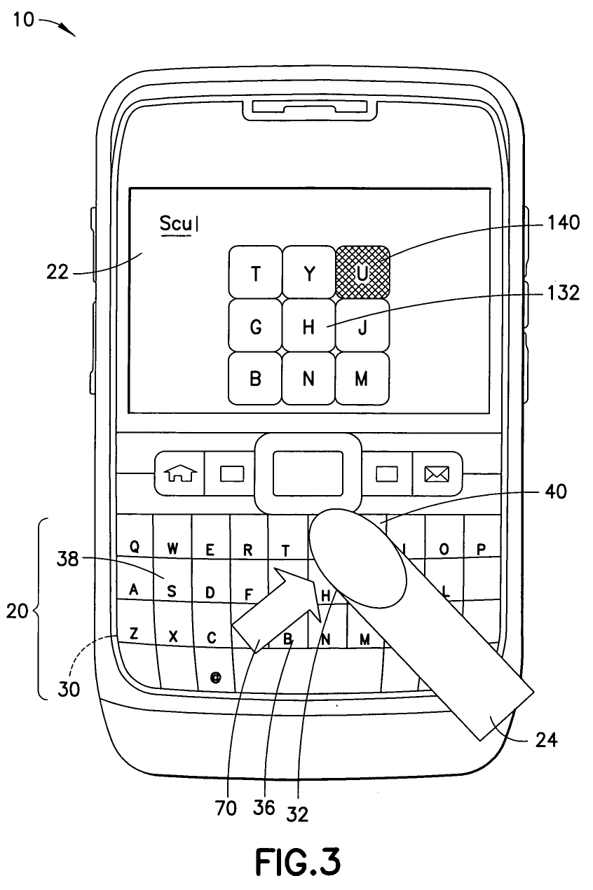

If the highlighted active key is not the correct one (or not the key intended to be pressed), then the user may move (or slide) his/her finger 24 towards the direction of the correct key. As shown in FIGS. 2 and 3, when the user first touches the keyboard 20, the sensor system 30 detects (or senses) the “H” key 32 as the intended key to be pressed (FIG. 2). However, if the user intended to press the “U” key 40, then the user may move his/her finger 24 in a direction 70 towards the “U” key 40 (FIG. 3). The sensor system 30 detects (or senses) the movement in the direction 70. The sensor system 30 is configured to indicate a selection of the key based on the determined direction of the touch movement on the keys. As shown in FIG. 3, the active (or highlighted) key changes from “H” (FIG. 2) to “U” (FIG. 3), illustrated as the virtual “H” key 132 and the virtual “U” key 140, in response to the detected movement in the direction 70, and shown in the display 22. Similar to above, if the highlighted active key is correct one (or the key intended to be pressed), then the user may press (or touch) the keyboard for the ‘second time’ to select (or confirm the selection) of the key. The press or touch on the keyboard (‘second time’) to confirm the selection of the key may be a press or touch on the selected key itself (in this example, the “U” key 40). Also similar to above, according to some embodiments the user's finger does not need to be on top of correct physical key, instead what is highlighted in the display 22 corresponds to the confirmed selection, and not where on the keyboard 20 the touch for the ‘second time’ occurs. The ‘second time’ press or touch to confirm the selection of the highlighted key may be performed on any of the keys on the keyboard 20. Such as a press on the “B” key 36, or a press on the “S” key 38, or any other key on the keyboard.

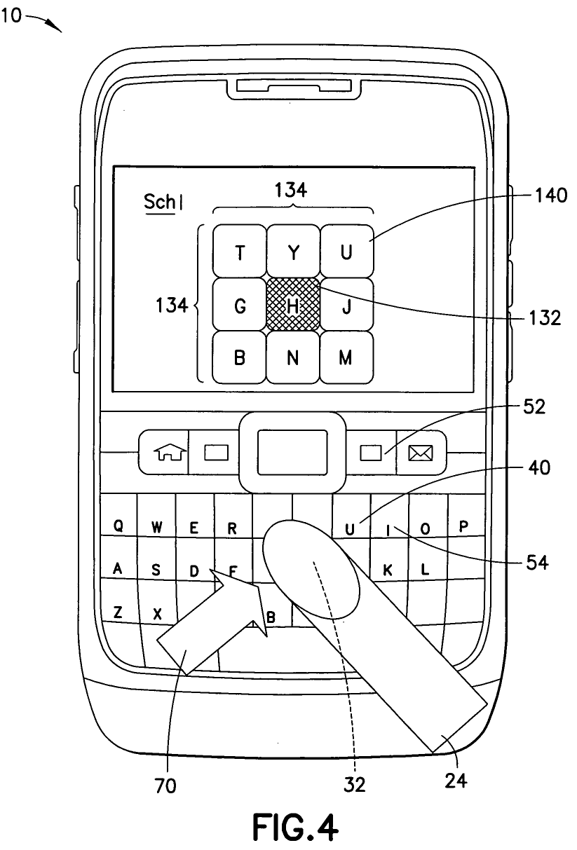

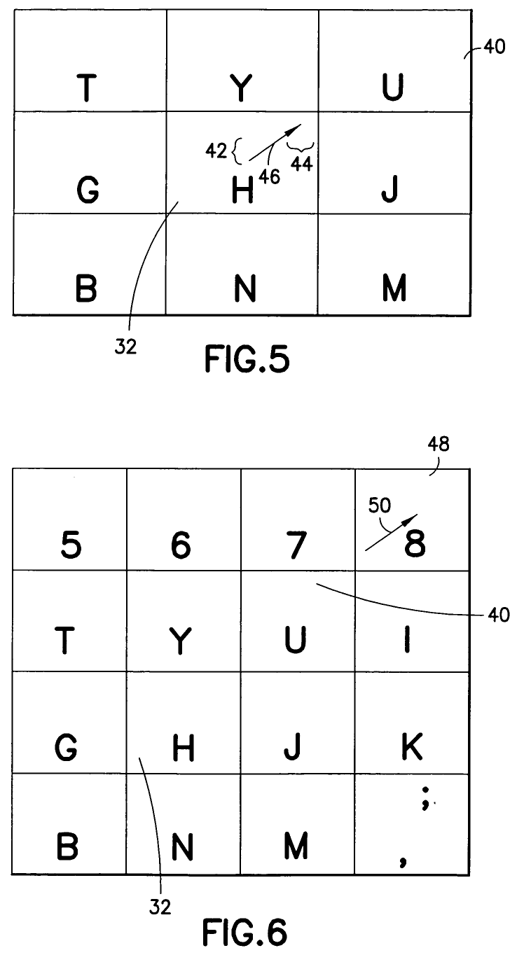

In addition to the procedure described above, when the user moves (or slides) his/her finger 24 towards the direction of the correct key (when the originally highlighted active key is not the correct one [or not the key intended to be pressed]), the user may only move his/her finger 24 in the correct direction according to what is displayed on the display 22. That is, if the user wants to press the “U” key 40 but places his finger on “H” key 32 (for example as in FIG. 4), the “H” key 32 is displayed on the screen (as the virtual “H” key 132) along with the surrounding keys (as the surrounding virtual keys 134). To move to the intended “U” key 40, the user may only move his/her finger 24 a small amount in the direction 70. An example would be the user moving his/her finger 24 from the middle 42 of the “H” key 35 to the top right corner 44 of the “H” key 32 (see also FIG. 5). This movement 46 (see FIG. 5) would be in the direction of the “U” key 40, and thus sensor system 30 would indicate a selection of the “U” key 40 (as the highlighted virtual “U” key 140) based on the movement sensed on the “H” key 32. This allows for the sensor system 30 to indicate a selection of a first one of the keys of the keyboard 20 in response to a sensed movement at a distance from the first one of the keys of the keyboard 20. In another example, if the user moves his/her finger 24 a large amount, the selection of the “U” key 40 may be indicated in response to a movement on a key beyond the “U” key 40. The key beyond the “U” key 40 may be the “8” key 48 for embodiments having the numbered keys “1-9” and “0” above the “QWERTY” layout (for example see movement 50 in FIG. 6), or a function key 52, or the “I” key 54, for example. Similar to above, to select the “U” key 40 after it is highlighted, then the user may press (or touch) the keyboard 20 for the ‘second time’ to select (or confirm the selection) of the key. The display 22 is updated to indicate which key will be assumed to be pressed, irrespective of what key is under the user's finger 24. For example, the user's finger 24 may still be on the “H” key 32 or on the “8” key 48, without touching or coming into contact with the “U” key 40.

According to some embodiments of the invention, the surrounding keys (or the surrounding virtual keys 134 shown in the display 22) may disappear from view in the display 22 when the user takes his/her finger 24 away from a detection distance of the sensor system 30 and then the user can select new “starting” letter. If, for example, the next letter the user wants to type is already amongst the displayed virtual surrounding keys 134 (shown in the display 22), then the user does not need to take his/her finger 24 away from the keyboard 20. The user may continue (with the touch on the keyboard 20) in the same area by sliding his/her finger 24 another direction (of the next letter) until the intended key is highlighted and, and then the user may press the keyboard for the ‘second time’, as described above, to confirm the selection.

It should be noted that although the examples above have been generally made with the “H” key 32 and the “U” key 40 (and the corresponding virtual keys 132, 140), embodiments of the invention may be utilized for any key. Further, according to some embodiments of the invention, the above described selection process may be utilized for function keys, ‘soft keys’, or any other user input feature.

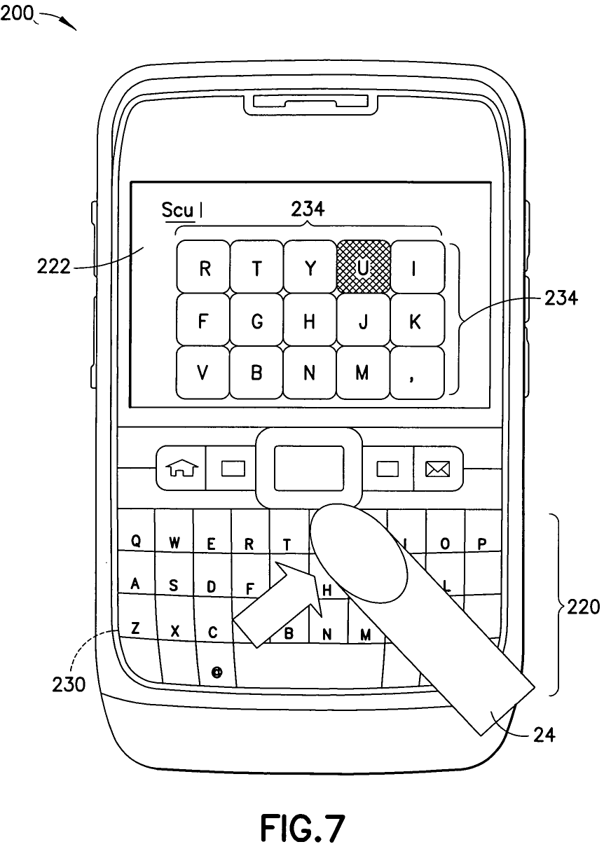

Referring now also to FIG. 7, a device 200 according to another embodiment of the invention is shown. The device 200 is similar to the device 10 and comprises a user input region 220, a display 222, and a sensor system 230. Additionally, the device 200 is configured, in a similar fashion as described above for the device 10, to provide an improved keyboard typing experience for portable electronic devices by sensing touches and movements on the keyboard 220. However, one difference between the device 200 and the device 10 is that the device 200 is configured to display additional virtual surrounding keys 234. For example, in the embodiment shown in FIG. 7, a group of fourteen surrounding keys are displayed when the sensor system 230 detects the user's finger 24. However, it should be noted that any suitable number or pattern/orientation of surrounding virtual keys may be provided.

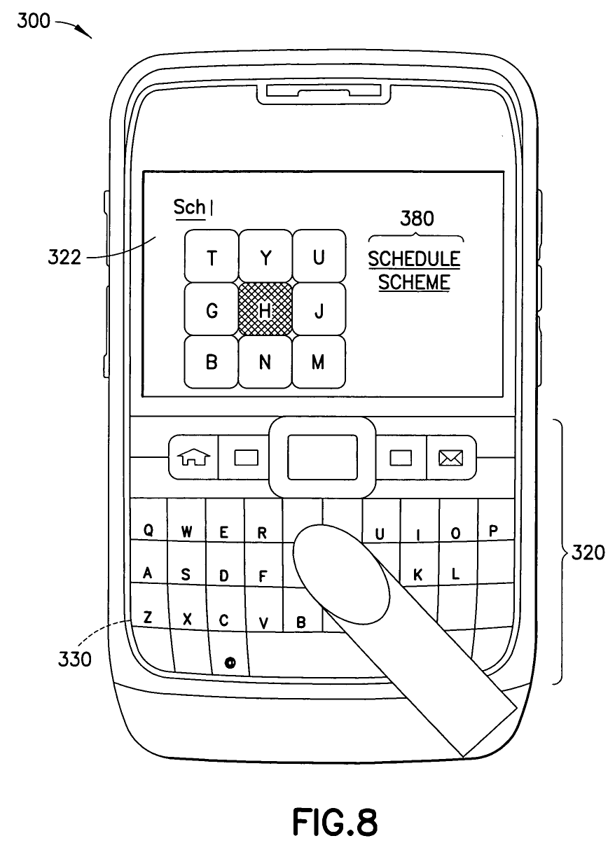

Referring now also to FIG. 8, a device 300 according to another embodiment of the invention is shown. The device 300 is also similar to the device 10 and comprises a user input region 320, a display 322, and a sensor system 330. Additionally, the device 300 is configured, in a similar fashion as described above for the device 10, to provide an improved keyboard typing experience for portable electronic devices by sensing touches and movements on the keyboard. However, one difference between the device 300 and the device 10 is that the device 300 is configured to display ‘intelligence’ features integrated in the device on the display 322 while using the user input region 320. For example, one feature may provide for a display of proposed words 380 based on the most common words or next letters corresponding to the keys of the keypad 320 already pressed by the user. After clicking or pressing the key(s) for the first few letters of the word (such as “sch” as shown in FIG. 8), the user may select the correct word from the list (such as “schedule” or “scheme” as shown in FIG. 8) by using a rocker key or a function key of the device, or any other suitable user input operation, for example.

Conventional device configurations generally have small keyboards with limited user input functionality wherein the user's finger tends to hide several keys of keyboard which may cause difficulties in knowing what key(s) the user of the device is pressing. Additionally, conventional configurations having half “QWERTY” keyboard layouts or ITU-T keyboard functionality generally do not allow a user of the device to visualize the key(s) that is pressed (to help with the typing operation) in an efficient manner.

Technical effects of any one or more of the exemplary embodiments allow users to visualize the keyboard on the display and change a selected key by sensing movements on the keyboard. For example, a user viewing the display can see what key(s) are being pressed in the user input region. This allows for a user to have “visibility” to keys (on the display) even when the user's finger is hiding the actual physical key(s). Examples of the invention may provide for less mis-presses (or inadvertent key touches), as small movements on the keyboard may only change the highlighted key, and the change can be seen in the display before confirming the selection. Examples of the invention may also allow for a smaller keyboard size (as the keys can be viewed on the display during keyboard operations).

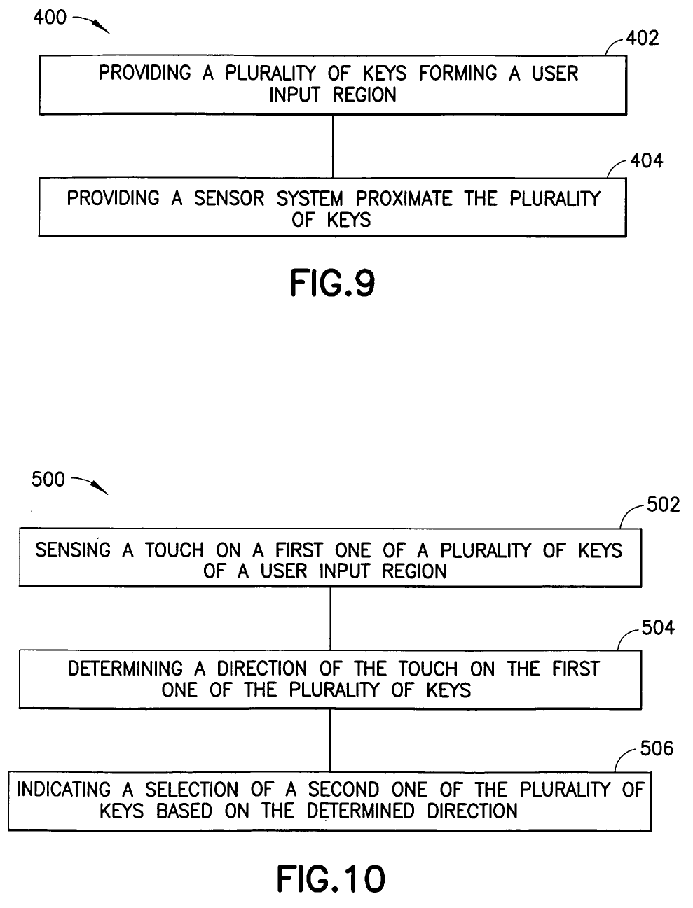

FIG. 9 illustrates a method 400. The method 400 includes the following steps. Providing a plurality of keys forming a user input region (step 402). Providing a sensor system proximate the plurality of keys, wherein the sensor system is configured to indicate a selection of a first one of the plurality of keys in response to a movement on the user input region at a distance from the first one of the plurality of keys (step 404). It should be noted that any of the above steps may be performed alone or in combination with one or more of the steps.

FIG. 10 illustrates a method 500. The method 500 includes the following steps. Sensing a touch on a first one of a plurality of keys of a user input region (step 502). Determining a direction of the touch on the first one of the plurality of keys (step 504). Indicating a selection of a second one of the plurality of keys based on the determined direction of the touch on the first one of the plurality of keys (step 506). It should be noted that any of the above steps may be performed alone or in combination with one or more of the steps.

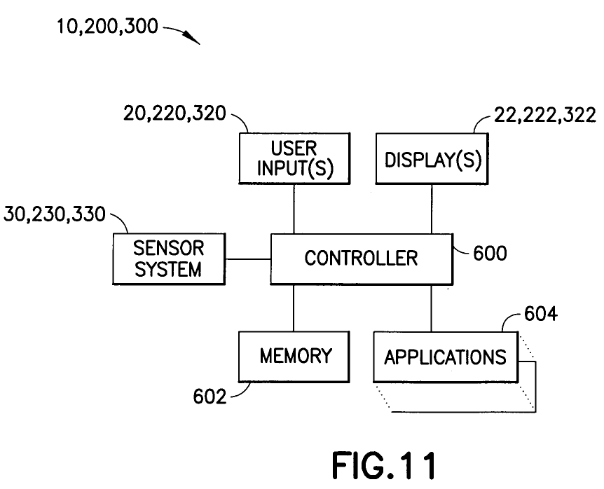

Referring now also to FIG. 11, the device 10, 200, 300 generally comprises a controller 600 such as a microprocessor for example. The electronic circuitry includes a memory 602 coupled to the controller 600, such as on a printed circuit board for example. The memory could include multiple memories including removable memory modules for example. The device has applications 604, such as software, which the user can use. The applications can include, for example, a telephone application, an Internet browsing application, a game playing application, a digital camera application, a map/gps application, etc. These are only some examples and should not be considered as limiting. One or more user inputs 20, 220, 320 are coupled to the controller 600 and one or more displays 22, 222, 322 are coupled to the controller 600. The sensor system 30, 230, 330 is also coupled to the controller 600. The device 10, 200, 300 may programmed to automatically select a key of the user input region. However, in some embodiments, this may not be automatic. The user may actively select the key.

According to one example of the invention, an apparatus is disclosed. The apparatus includes a user input region and a sensor system. The user input region includes a plurality of keys. The sensor system is proximate the user input region. The sensor system is configured to determine a touch on a first one of the plurality of keys of the user input region. The sensor system is configured to determine a direction of the touch on the first one of the plurality of keys. The sensor system is configured to indicate a selection of a second one of the plurality of keys based on the determined direction of the touch on the first one of the plurality of keys.

According to another example of the invention, a program storage device readable by a machine, tangibly embodying a program of instructions executable by the machine for performing operations to select a key of a user input region is disclosed. A touch on a first one of a plurality of keys of a user input region is sensed. The first one and a second one of the plurality of keys are displayed on a display. The second one of the plurality of keys is highlighted on the display in response to a movement on the first one of the plurality of keys.

It should be understood that components of the invention can be operationally coupled or connected and that any number or combination of intervening elements can exist (including no intervening elements). The connections can be direct or indirect and additionally there can merely be a functional relationship between components.

It should be understood that the foregoing description is only illustrative of the invention. Various alternatives and modifications can be devised by those skilled in the art without departing from the invention. Accordingly, the invention is intended to embrace all such alternatives, modifications and variances which fall within the scope of the appended claims.

1. An apparatus comprising a user input region and a sensor system, wherein the user input region comprises a plurality of keys, wherein the sensor system is proximate the user input region, wherein the sensor system is configured to determine a touch on a first one of the plurality of keys of the user input region, wherein the sensor system is configured to determine a direction of the touch on the first one of the plurality of keys, and wherein the sensor system is configured to indicate a selection of a second one of the plurality of keys based on the determined direction of the touch on the first one of the plurality of keys.

2. An apparatus as in claim 1 wherein the apparatus is configured to display the first one and the second one of the plurality of keys on a display of the apparatus.

3. An apparatus as in claim 2 wherein the apparatus is configured to highlight the first one or the second one of the plurality of keys on the display based on the determined direction of the touch.

4. An apparatus as in claim 1 wherein sensor system is configured to indicate a selection of a virtual key and/or a soft key of the apparatus based on the determined direction of the touch on the first one of the plurality of keys.

5. An apparatus as in claim 1 wherein the sensor system is configured to indicate a selection of the second one of the plurality of keys based on a determined direction of a touch on another one of the plurality of keys, wherein the another one of the plurality of keys is spaced from the second one of the plurality of keys.

6. An apparatus as in claim 5 wherein the second one of the plurality of keys is between the first one of the plurality of keys and the another one of the plurality of keys.

7. An apparatus as in claim 1 wherein the apparatus is a portable electronic device.

8. A method comprising:
providing a plurality of keys forming a user input region; and
providing a sensor system proximate the plurality of keys, wherein the sensor system is configured to indicate a selection of a first one of the plurality of keys in response to a movement on the user input region at a distance from the first one of the plurality of keys.

9. A method as in claim 8 wherein the installing of the sensor system further comprises installing a capacitive touch sensor system proximate the plurality of keys.

10. A method as in claim 8 wherein the installing of the sensor system further comprises integrating the sensor system with the plurality of keys.

11. A method as in claim 8 wherein the sensor system is configured to indicate the selection of the first one of the plurality of keys in response to a movement on the user input region at a second one of the plurality of keys.

12. A method as in claim 8 wherein the sensor system is configured to indicate a selection of a second one of the plurality of keys in response to a movement on the user input region at a distance from the first one of the plurality of keys.

13. A method comprising:
sensing a touch on a first one of a plurality of keys of a user input region;
determining a direction of the touch on the first one of the plurality of keys; and
indicating a selection of a second one of the plurality of keys based on the determined direction of the touch on the first one of the plurality of keys.

14. A method as in claim 13 wherein the indicating of the selection of the second one of the plurality of keys further comprises highlighting the selection of the second one of the plurality of keys on a display.

15. A method as in claim 13 wherein the indicating of the selection of the second one of the plurality of keys further comprises indicating the selection of the second one of the plurality of keys based on a determined direction of a touch on a third one of the plurality of keys.

16. A method as in claim 13 further comprising:
confirming the selection of the second one of the plurality of keys in response to another touch on any one of the plurality of keys.

17. A program storage device readable by a machine, tangibly embodying a program of instructions executable by the machine for performing operations to select a key of a user input region, the operations comprising:
sensing a touch on a first one of a plurality of keys of a user input region;
displaying the first one and a second one of the plurality of keys on a display; and
highlighting the second one of the plurality of keys on the display in response to a movement on the first one of the plurality of keys.

18. A program storage device as in claim 17 wherein the highlighting of the second one of the plurality of keys further comprises selecting the second one of the plurality of keys.

19. A program storage device as in claim 18 further comprising:
confirming a selection of the second one of the plurality of keys in response to another touch on any one of the plurality of keys.

20. A program storage device as in claim 17 wherein the highlighting of the second one of the plurality of keys further comprises highlighting the second one of the plurality of keys on the display in response to a movement on a third one of the plurality of keys.
